(19) United States
(12) Patent Application Publication
(10) Pub. No.: US 2011/0143018 A1
(43) Pub. Date: Jun. 16, 2011

(54) Methods and systems for making battery electrodes and devices arising therefrom

(76) Inventors: Shufu Peng, Sunnyvale, CA (US); Lawrence S. Pan, Los Gatos, CA (US)

(21) Appl. No.: 12/876,079

(22) Filed: Sep. 3, 2010

Related U.S. Application Data
(60) Provisional application No. 61/275,852, filed on Sep. 3, 2009.

(51) Int. Cl. B05D 5/12; C23C 14/54; B82Y 30/00; B82Y 40/00

(52) U.S. Cl. 427/9; 427/600; 427/457; 427/78; 977/948; 977/842; 977/742

(57) ABSTRACT

The invention provides, in preferred embodiments, methods, systems, and devices arising therefrom for making battery electrodes, in particular, for lithium-ion batteries. Unlike conventional slurry coating methods that use mechanical means to coat thick pastes of active material, other materials, and solvent(s) onto a substrate, the invention provides for a method to produce electrode coatings onto support in a multi-layer approach to provide highly uniform distribution of materials within the electrode. Problems of differential sedimentation of particles in slurries found in conventional methods are minimized with the methods of the present invention. Also included are systems for producing in large-scale the battery electrodes of the invention. Further included are electrodes produced by the methods and systems described herein.

### FIELD OF THE INVENTION

The invention generally relates to the field of battery electrode manufacturing, preferably lithium-ion battery electrode manufacturing. The invention generally pertains to the field of energy storage, batteries, lithium-ion (Li-ion) batteries, advanced vehicles technology, and reduction of national reliance upon foreign petroleum products. The invention also relates to manufacturing systems for applying a coating or coatings to surfaces of substrates. The invention further relates to the field of energy efficiency, and environmental protection.

### BACKGROUND

Lithium ion batteries play an important part in today's high-technology world. Reaching new markets, lithium ion batteries offer the promise of high energy capacity/high power output in relatively lightweight and compact formats when compared to traditional lead acid, nickel metal anhydride, or nickel cadmium batteries.

Traditional methods for making lithium ion batteries generally include the formation of a slurry comprising a solvent and a mixture of particles. The slurry is then spread out upon the surface of a substrate, typically a metal foil, then dried and calendared to a desired thickness and density. Problems exist with the slurry coating method, whether by doctor blade or by slot die process, in that generally only one layer can be deposited upon the surface of the substrate. Depositing additional layers using doctor blade and slot die methods runs the risk of delaminating the earlier deposited layers due to the forces applied against the substrate as it is pulled across the doctor blade or slot die head.

Another problem with traditional battery making methods is that because thick layers are deposited to achieve the desired energy density for the electrode, the period of time it takes for the solvent to evaporate from the deposited slurry is considerable. During this time while the slurry is wet, particles of differing sizes and rheological behavior will sediment at different rates thus causing a stratification of the soon to solidify electrode matrix. Stratification leads to less than optimal performance because the different particles within the electrode matrix are not spatially distributed evenly.

There has been a trend towards using nanometer scale sized active material particles for electrodes. Not wishing to be bound by theory, it is believed that nano-scale particles present a problem, however, because they have a greater number of particles per unit mass than micrometer scale particles typically used in commercially available cells. Unless higher than average amounts of conductive particles like carbon black are used, the increased number of active material particles increases the internal resistance of the electrode. Internal resistance causes power loss through heating and can contribute to thermal runaway and flame. Nanoparticles, however, can be used by substituting carbon nanotubes instead of or in combination with carbon black. The inside diameter of carbon nanotubes, compared to their outside dimension, greatly reduces the number of effective interfaces in the electrical conductive path. A problem exists, however, in using carbon nanotubes in that they tend to aggregate. Likewise, active material nano-scale particles tend to aggregate as well. Aggregation can pose a problem with coating surfaces to form electrodes using a slurry based process.

Accordingly, there is a need for a method for depositing materials onto a substrate for the purposes of making battery electrodes that provides for uniform distribution of particles within the electrode matrix. There is also a need for a method for depositing materials onto a substrate that avoids the need for using toxic organic chemical as a solvent. Embodiments of the invention address the above noted problems and other problems, individually and collectively.

### BRIEF SUMMARY OF THE INVENTION

Among addressing other problems, it is an object of the invention to address the problems mentioned above in making advanced battery components. Towards this end, the invention aims to provide superior methods for manufacturing electrodes for use in batteries, preferably lithium ion batteries. The invention provides, in one aspect, a method for coating a substrate using multi-coat spraying. In preferred embodiments, the method comprises the steps of: providing a substrate having a surface; providing an active material suspension comprising: active material particles; and, electrically conductive particles; a solvent; spraying the active material suspension onto the substrate surface to form a first coating layer; evaporating at least 50% of the solvent, if any, from the first coating layer; repeating the steps (c) through step (e) for at least two repetitions.

In preferred embodiments, the steps (c) and (d) are repeated at least five times. In more preferred embodiments, steps (c) and (d) are repeated at least ten times. And, in highly preferred embodiments, steps (c) and (d) are repeated at least twenty times.

In certain embodiments, the active material suspension is sprayed using an aerosol sprayer, more preferably, an airless sprayer, and yet even more preferably an ultrasonic sprayer. It is highly preferred to use a pulse width modulated sprayer, and wherein the active material suspension is sprayed in a volumetrically controlled manner.

In another embodiment, the invention provides for a method wherein the evaporating step further comprises detecting the amount of solvent in the coating layer. In preferred embodiments, the coating layer is dried to a content level of about less than 20% w/w prior to repeating the spraying step. In particularly preferred embodiments, the thickness of the coating layer is measured prior to the repeating of the spraying and evaporating steps. In some embodiments, the density of the coating layer is measured prior to the repeating of the spraying and evaporating steps.

In highly preferred embodiments, the active material particles comprise a battery electrode active material. In some embodiments, the electrically conductive particles comprise carbon, more preferably, carbon comprises carbon nanotubes, and yet more preferably, carbon comprises graphitic carbon, and yet other embodiments, the carbon is carbon black. In highly preferred embodiments, the electrically conductive particles comprise a mixture of carbon particles mentioned above.

In highly preferred embodiments, the solvent is a non-organic solvent, and in some embodiments, the solvent is an organic solvent. In particularly preferred embodiments, the solvent comprises water. In some embodiments, the solvent comprises ethanol. In certain preferred embodiments, the solvent comprises acetone, and/or N-methylpyrrolidone.

In particularly preferred embodiments, the battery active material reversibly stores lithium ions.

In one aspect of the invention, the spraying step is operationally linked to a detector monitoring at least one attribute of the coating layer so that the spray volume is adapted in real-time in response to control, wholly or partly, a degree of the attribute.

In certain embodiments of the invention, the substrate is wound about an axis to form a substrate roll and the substrate is unwound from the roll and is traversed through a spraying region wherein the first spraying step occurs. In highly preferred embodiments, the substrate first traverses through the spraying region and then traverses through a evaporating region where the first evaporating step occurs. In highly preferred embodiments, the substrate subsequently traverses through a second spraying region then a second evaporating region and so forth until a desired number of coating layers are built upon the substrate surface. In some embodiments, the substrate further comprises a second surface on a side of the substrate opposite the first substrate surface. In particularly preferred embodiments, the spraying step and the evaporating step are applied simultaneously to the first and the second substrate surfaces to form a first coating layer upon the substrate first surface and a second coating layer upon the substrate second surface to yield a double-sided coating on the substrate surfaces. In some embodiments, the spraying step and the evaporating step are applied alternately to the first and the second substrate surfaces to form a first coating layer upon the substrate first surface and a second coating layer upon the substrate second surface to yield a double-sided coating on the substrate surfaces. In some embodiments, a subsequent coating layer comprises materials different from the active material particles and the electrically conductive particles.

In preferred embodiments, the evaporating step further comprises providing a heat source, preferably where the heat source comprises an infrared heating element, and/or a where the heat source comprises a gas-catalytic heat source, and/or where the heat source comprises a radio frequency transmitter, and/or the heat source comprises a convective heat element.

In certain embodiments, the evaporating step further comprises providing an air flow apparatus for passing air across the surface of the substrate during the evaporating step, preferably where the air passing across the surface of the substrate surface is heated, and/or the air passing across the surface of the substrate is not heated, and/or the air passing across the surface of the substrate is cooled.

In some embodiments, the heat source further comprises two or more air flow apparatuses wherein at least one air flow apparatus passed heated air across a portion of the surface of the substrate at one point in time and then passes cooled air across the portion of the surface of the substrate at another point in time.

In certain embodiments, the active material particles comprise nanometer scale sized active material particles, preferably where the active material particles comprise nano-structured materials, and/or where the active material particles contain micrometer scale sized active material particles. In highly preferred embodiments, the active material particles comprise a cathode active material capable of reversibly storing an ion. In some embodiments, the cathode active material comprises a cathode active material selected from the group consisting of: LiFePO₄; LiCoO₂; LiMnO₂; LiMn₂O₄; LiMn_{1/2}Ni_{1/2}O₂; and, Li (Ni_{1/3}Mn_{1/3}CO_{1/3})O₂.

In some embodiments, the active material particles comprise an anode active material capable of reversibly storing an ion, preferably where the anode active material may be carbon; graphite; graphene; carbon nanotubes; silicon; porous silicon; nanostructured silicon; nanometer scale silicon; micrometer scale silicon; alloys containing silicon; carbon coated silicon; carbon nanotube coated silicon; tine; alloys containing tin; and/or Li₄Ti₅O₁₂. In highly preferred embodiments, the active material particles further comprise lithium ions stored therein.

In some embodiments, the electrically conductive particles comprise carbon, whereas in some embodiments, the electrically conductive particles comprise at least one metal element. In certain embodiments, the carbon may be carbon; amorphous carbon; carbon black; carbon nanotubes; single-walled carbon nanotubes; multi-walled carbon nanotubes; carbon nanorods; carbon nanofoam; nanostructured carbon; carbon nanobuds; Buckminster fullerenes; linear acetylenic carbon; metallic carbon; Lonsdaleite; diamond; graphite; and/or, graphene.

In certain embodiments, the metal element may be ruthenium; rhodium; palladium; silver; osmium; iridium; platinum; and/or, gold.

In preferred embodiments, the solvent comprises water, the solvent comprises an organic solvent, and/or the solvent comprises a mixed solvent comprising at least two different solvents. In certain embodiments, the solvent may be a polar solvent, polar aprotic solvent; and/or, a non-polar solvent. In some embodiments, the solvent may be water; methanol; ethanol; propanol; isopropanol; butanol; tert-butanol; pentane; hexane; heptane; acetone; dimethylformamide; n-methyl-2-pyrrolidone; and/or, 1,3-dimethyl-2-imidazolidinone.

In some embodiments, the substrate comprises a metal, a non-metal, or both. In certain embodiments, the substrate comprises a woven material, a non-woven material, or both. In some embodiments, the substrate is porous or non-porous, or comprises both porous and non-porous portions. In particularly preferred embodiments, the substrate is a foil. In some embodiments, the substrate comprises a film. In certain embodiments, the substrate comprises a plurality of layers, preferably two or more of the plurality of layers are different, and/or two or more of the plurality of layers are the same. In highly preferred embodiments, the substrate comprises copper, aluminum, or both.

The invention provides, in another aspect, a system for making a battery electrode comprising: an unwinder; a rewinder; a plurality of spray/dry regions disposed between the unwinder and the rewinder, each spray/dry region comprising: a sprayer in liquid communication with a liquid suspension source; a dryer in fluid communication with a gas source, the dryer being immediately preceded the spray region.

In preferred embodiments, the plurality of spray/dry regions comprises at least two spray/dry regions. In even more preferred embodiments, the plurality of spray/dry regions comprises at least five spray/dry regions. In still more preferred embodiments, the plurality of spray/dry regions comprises at least ten spray/dry regions. In particularly preferred embodiments, the plurality of spray/dry regions comprises at least twenty spray/dry regions.

These and other embodiments of the invention are described in further detail below with reference to the Figures and the Detailed Description

### BRIEF DESCRIPTION OF THE SEVERAL VIEWS OF THE DRAWING

FIGS. 1A and 1B depict a substrate traversing from a spraying region to a drying region in an embodiment of the invention.

FIG. 2 depicts a roll-to-roll spray/dry embodiment of the invention.

FIG. 3 depicts a roll-to-roll multiple spray/dry region embodiment of the invention.

FIG. 4 depicts a roll-to-roll multiple spray/dry/cool embodiment of the invention.

FIG. 5 depicts a roll-to-roll multiple heat/spray/dry embodiment of the invention.

FIG. 6 depicts a typical pulse wave signal used to control a pulse-width modulated spray head embodiment of the invention.

FIGS. 7A and 7B depict a preferred spray head of the invention in two different states.

FIG. 8 depicts an ultrasonic multi-orifice spray head employed in a preferred embodiment of the invention.

FIG. 9 depicts a flow-chart showing the logic flow of a feedback-loop operated spray deposition system of a preferred embodiment of the invention.

FIGS. 10A-10C depict images of sample electrodes produced using a preferred method of the invention.

FIGS. 11A-11C depict scanning microscopic images of sample electrodes produced using a preferred method of the invention.

FIG. 12 depicts charge/discharge curves graphically for a sample electrode produced using a preferred method of the invention.

FIGS. 13A-13B depict a capacity profile for two sample electrodes produced using a preferred method of the invention.

FIG. 14 depicts a voltage v. time profile for a sample electrode produced using a preferred method of the invention.

FIG. 15 depicts charge v. current profiles for two sample electrodes produced using a preferred method of the invention and a commercially available electrode.

FIG. 16 depicts a capacity v. current profile for two sample electrodes produced using a preferred method of the invention.

FIG. 17 depicts a capacity v. half-cycle number graph for two sample electrodes produced using a preferred method of the invention.

FIG. 18 depicts a scanning electron micrograph of a sample electrode produced using a preferred method of the invention.

FIGS. 19A-19B depict images of sample electrodes produced using a preferred method of the invention.

FIG. 20 depicts a voltage v. time profile for a sample electrode produced using a preferred method of the invention.

FIG. 21 depicts charge and discharge curves for a sample electrode produced using a preferred method of the invention.

FIGS. 22A-22B depict capacity v. half-cycle number graphs for two sample electrodes produced using a preferred method of the invention.

FIG. 23 depict a power curve for two sample electrodes produced using a preferred method of the invention.

FIG. 24 depicts a power curve for two sample electrodes produced using a preferred method of the invention and a commercially available electrode.

### DETAILED DESCRIPTION OF THE INVENTION

The invention provides for methods for making battery electrode and systems, apparatuses for making battery electrodes and devices arising there from. Preferred embodiments of the invention provides for methods, systems, and apparatuses for making electrodes for use in lithium-ion batteries.

The invention provides for, in one aspect, for a coating system that sprays a suspension of battery electrode materials onto a substrate, preferably a metal foil substrate. The preferred embodiments of the invention differ from the prior art in at least one fundamental way. These embodiments build up an electrode matrix in numerous layers rather than by one relatively thick slurry coating. The problem with the latter includes, but is not limited to differential sedimentation of electrode materials (particle) during the drying process that creates an electrode having an inhomogeneous composition with respect to the thickness dimension of the coated electrode.

Currently, there is a trend towards using smaller and smaller sized active material particles in battery electrodes for lithium-ion cells. Not wishing to be bound by theory, the inventors believe that as the particle size lessens, the tendency for the particles to aggregate and sediment out of the wet curing electrode made by slurry coating will result in losing the benefits of the smaller sized particles, for example, but not limited to, higher surface area to mass ratio and better ion diffusion rates. Moreover, it is believed that differential sedimentation causes inefficient distribution of conductive materials and active materials within the electrode matrix thus causing some parts of the electrode matrix to have lower conductivity than others while yet other parts of the electrode matrix have different amounts and characteristics of active material particles.

To address these problems, and others, applicants have invented a system that provides for a higher level of intra-electrode homogeneity when compared to standard slurry coating methods using one-step doctor blade or slot die type application of the electrode coating to the substrate foil current collector. By applying thin layers by spray and rapidly drying each layer, a plurality of layers of electrode material are built up to form an electrode matrix having a high degree of homogeneity with respect to spatial particle distribution and minimized homo-particle aggregation.

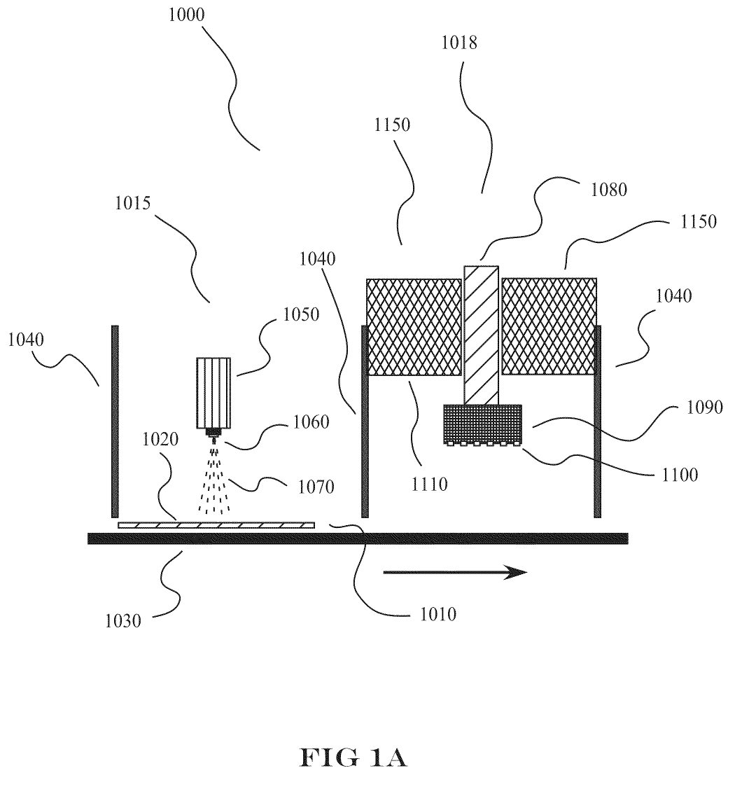

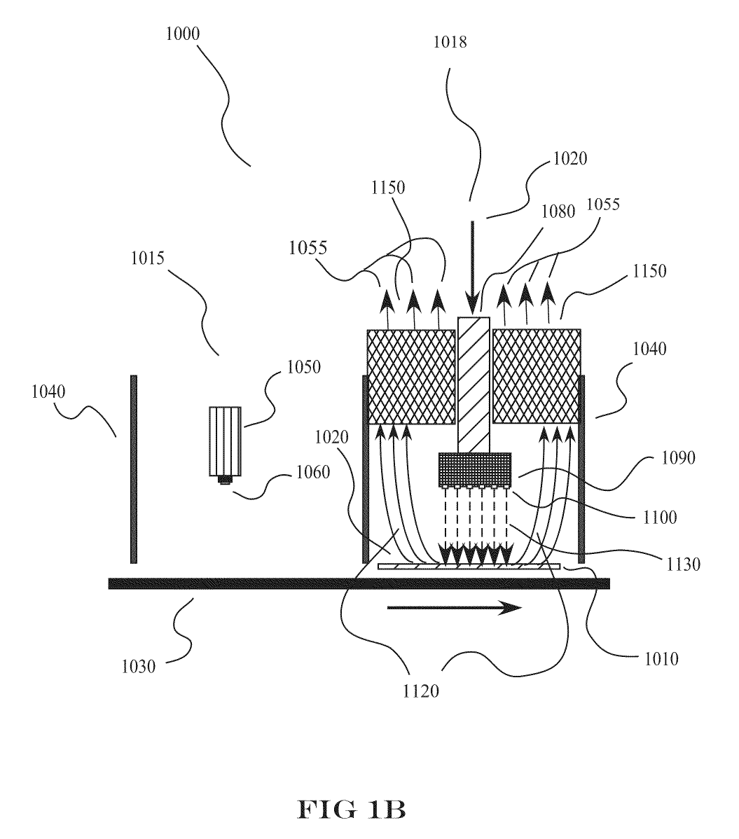

Turning now to FIG. 1A, an exemplary embodiment of the invention is shown. Spray/Dry System 1000 operates by traversing Substrate 1010 from Spraying Region 1015 to Drying Region 1018. Spraying Region 1015 and Drying Region 1018 are separated from each other and external of Spray/Dry System 1000 by several Partitions 1040. Sprayer 1050 is supported inside Spraying Region 1015 and aimed towards Surface 1020 of Substrate 1010. Adjacent Spraying Region 1015 is Drying Region 1018 having therein Dryer 1080 in fluid communication with Dryer Manifold 1090 and Dryer Jets 1100.

Substrate 1010 is introduced into Spray System 1000 by way of Support Stage 1030 that passes under Partitions 1040 with Substrate 1010 thereupon. Once in Spray Region 1015, a coating is applied to Surface 1020 of Substrate 1010 by Sprayer 1050. Sprayer 1050 comprises Spray Tip 1060 from which Spray Mist 1070 emanates therefrom and travels towards Surface 1020 to form a layer of electrode material.

Depicted in FIG. 1B, Substrate 1020 traverses into Dryer Region 1018, Hot Air or Gas 1120 of Dryer Flow 1130 is passed through Dryer 1080 and Dryer Manifold 1090 out towards Surface 1020 of Substrate 1010. After impinging upon Surface 1010, the Hot Air or Gas 1120 is deflected upward and is scavenged from Dryer Region 1018 through Exhaust 1150 as Exhaust Flow 1055. After Substrate 1010 Surface 1020 is sufficiently dried, Substrate 1010 is traversed out of Dryer Region 1080 upon Support Stage 1030 onward to potentially further spray/dry steps or onto some other processing.

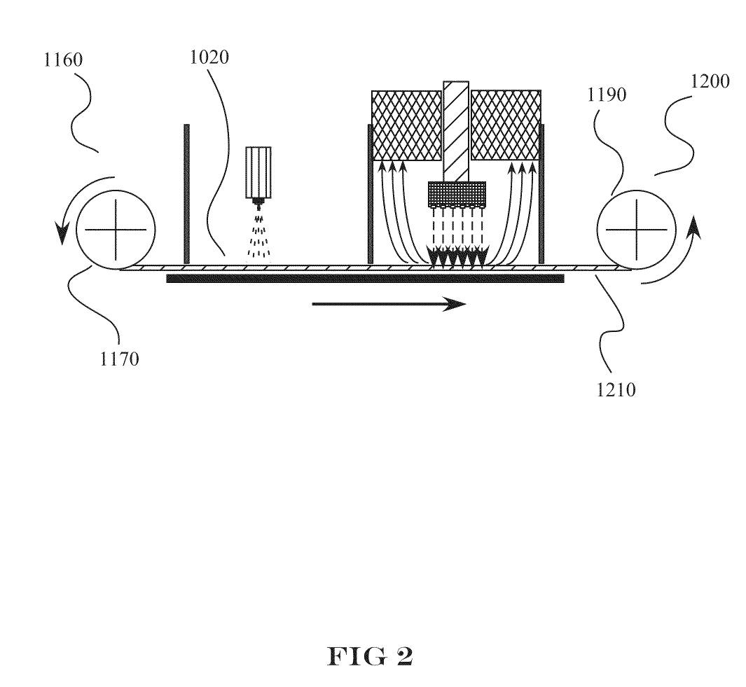

In highly preferred embodiments, the invention provides for a continuous coating system that relies on roll-to-roll type material handling similar to that of newspaper printing presses. FIG. 2 depicts a roll-to-roll spray/dry embodiment of the invention wherein Spray System 1000 is equipped with Unwinder 1160 and Rewinder 1190 where supported thereon are Unwind Roll 1170 and Rewind Roll 1200 loaded with Continuous Substrate 1210 that is in the form of a long ribbon-like material that arrives at Sprayer System 1000 wound upon Unwind Roll 1070 and wherein Continuous Substrate 1210 traverses Spray System 1000 ultimately terminating on Rewind Roll 1200 wherein Continuous Substrate 1210 is wound thereupon during a coating run. When finished, Rewind Roll 1200 should have wound thereabouts Continuous Substrate 1210 with Surface 1020 coated with electrode material. The continuous process generally has both Spray 1050 and Dryer 1080 active simultaneously or near simultaneously.

In highly preferred embodiments, the invention provides for a continuous coating system similar to that depicted in FIG. 2, except that a plurality of Spray Systems 1000 are arranged serially between Unwinder 1160 and Rewinder 1190 to form Spray Line 1001.

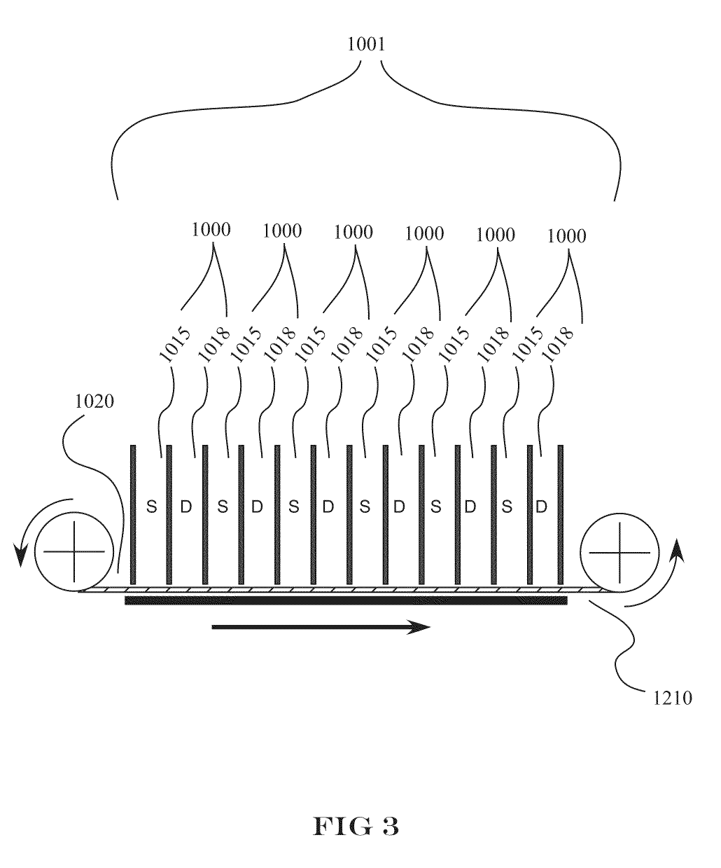

FIG. 3 depicts a roll-to-roll multiple spray/dry region embodiment of the invention. Each Spraying Region 1015 and Drying Region 1018 is arranged in alternating fashion to permit multiple layers to be applied to Surface 1020 of Continuous Substrate 1210. The rate for which Continuous Substrate 1210 is fed through Spray Line 1001 is preferably set to a speed wherein a substantial amount of solvent is removed from the coating prior to each subsequent coating cycle. This is believed to help minimize segregation of particles within the electrode coating during the drying process. In certain embodiments, a preceding layer is allowed to dry to a point that sedimentation is substantially halted even though some amount of solvent may still be present within the preceding layer prior to applying a subsequent layer of electrode material.

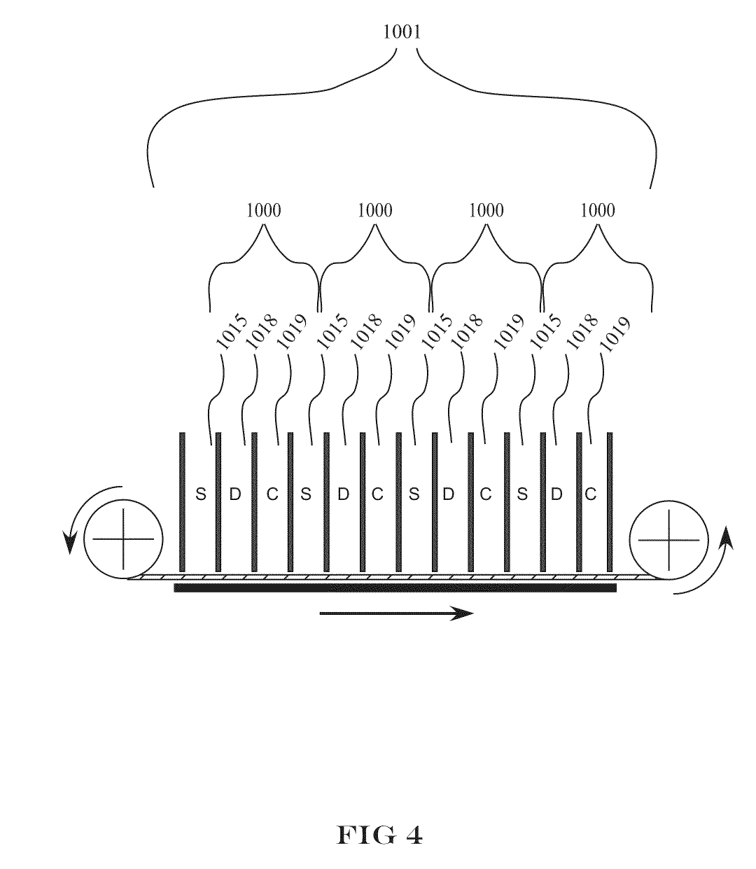

FIG. 4 depicts a roll-to-roll multiple spray/dry/cool embodiment of the invention. In some embodiments, it may be desirable to reduce the temperature of Surface 1020 prior to spraying on an additional layer of electrode material. This is to ensure that the freshly sprayed material has some period of time in liquid form to self level. If dried prematurely due to Surface 1020 being too hot from a preceding drying step, Cooling Region 1019 may be further incorporated into the Spray Line 1001 depicted in FIG. 3. Here, Spraying Region 1015 is followed by Drying Region 1018, and then by Chilling Region 1019 wherein the temperature of Surface 1020 is lowered to a desired level to facilitate spraying in a subsequent Spraying Region 1015.

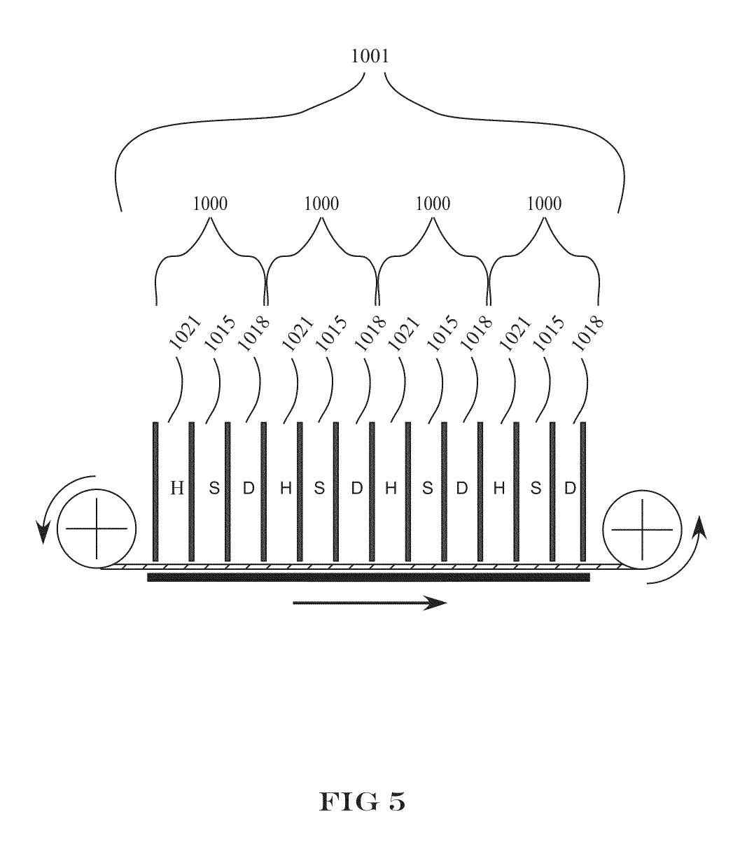

FIG. 5 depicts a roll-to-roll multiple heat/spray/dry embodiment of the invention. In some embodiments, it may be desirable to reduce the temperature of Surface 1020 prior to spraying on an additional layer of electrode material. This is to ensure that the freshly sprayed material has some period of time in liquid form to self level. If dried prematurely due to Surface 1020 being too hot from a preceding drying step, Heating Region 1021 may be further incorporated into the Spray Line 1001 depicted in FIG. 3. Here, Spraying Region 1015 is preceded by Heating Region 1021, and then by Drying Region 1018 wherein the temperature of Surface 1020 is raised to a desired level.

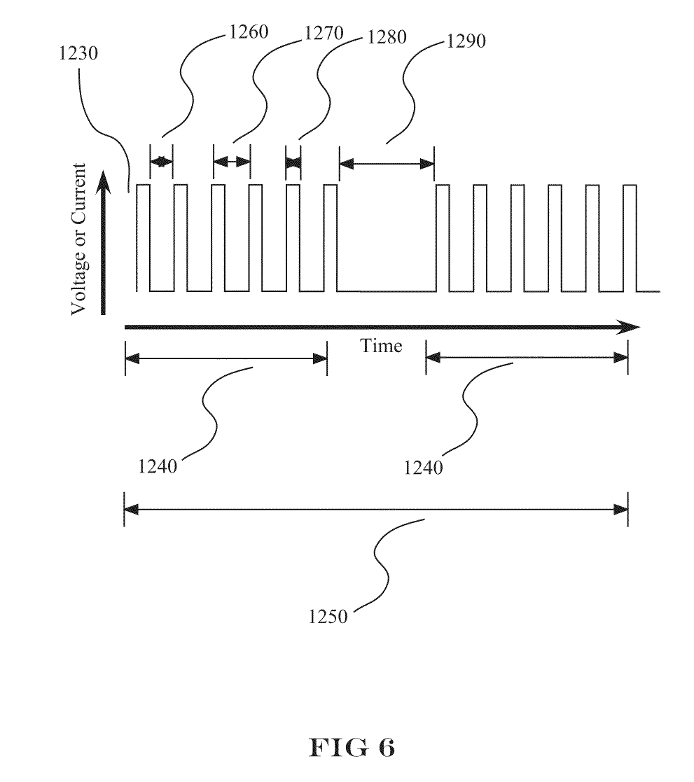

In certain embodiments, Sprayer 1050 is controlled in a pulsatile manner to control flow rates without altering spray patterns. FIG. 6 depicts a typical pulse wave signal used to control a pulse-width modulated spray head embodiment of the invention. Pulse Train 1220 comprises a series of voltage pulses organized in Pulse Trains 1240, Pulse Train Intervals 1290, and Pulse Profiles 1250. Within a Pulse Train 1240 are Pulses 1280 having a time dimension width between the leading edge of Pulse 1280 and the trailing edge of Pulse 1280, a Pulse Interval 1260 having a time dimension width between the trailing edge of a preceding Pulse 1280 and the leading edge of a immediately subsequent Pulse 1280, and Frequency 1270 having a time dimension width between the leading edge of two consecutive Pulses 1280. Each Pulse 1280 has Amplitude 1230 which can represent voltage amplitude or current flow.

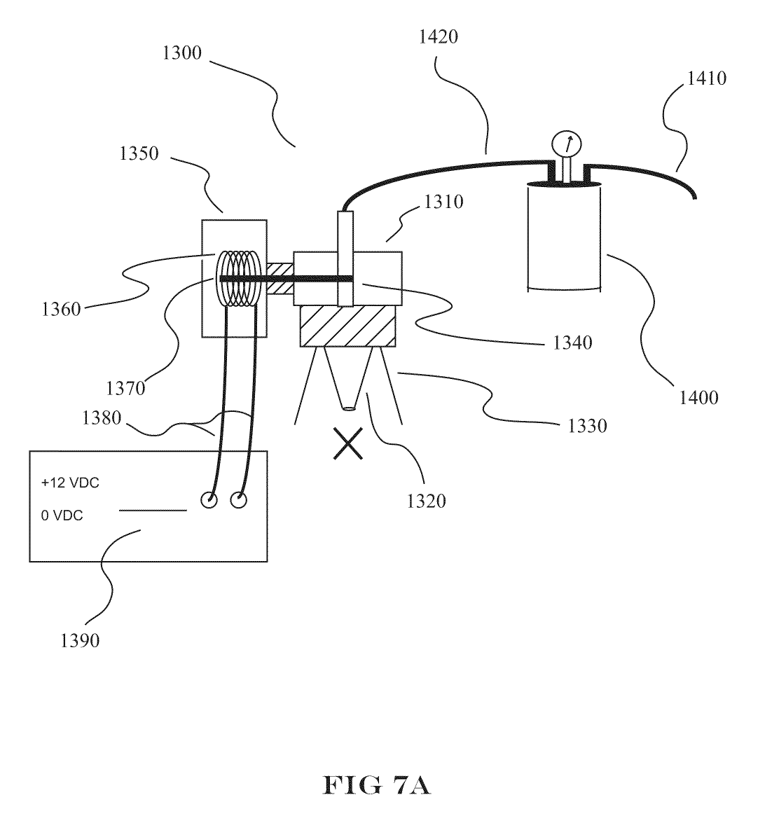

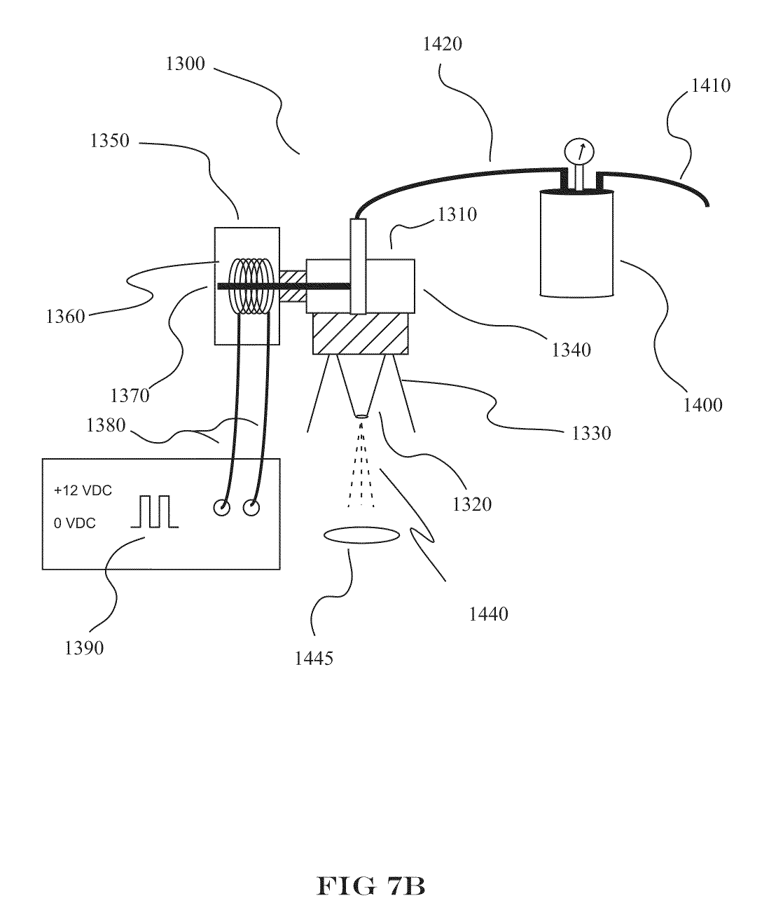

As depicted in FIG. 7A, in preferred embodiments, Spray System 1000 comprises a Pulse-Width Modulated (“PWM) Sprayer 1300 to precisely regulate coating flow rates while maintaining a consistent Spray Pattern 1445. Pulse-Width Modulated Sprayer 1300 comprises: Spray Head 1310 that includes, but is not limited to, Valve Body 1340 having associated therewith: Solenoid Actuator 1350 housing Coil 1360 and a portion of Plunger 1370; Spray Nozzle 1320 with Spray Guides 1330. Coil 1360 is in electrical communication through Leads 1380 with Pulse Generator 1390 that produces electrical pulses that actuate Solenoid Actuator 1350 to move Plunger 1370 into and out of Valve Body 1340 thus permitting and restricting the flow of coating suspension through Spray Head 1310 and forming Spray Pattern 1445. Tank 1400 is in fluid communication with Spray Head 1310 through Delivery Tube 1420. Coating Suspension, not shown, can be pumped to Spray Head 1310 using any pumping system. FIG. 7A depicts a gas pressure pumping system wherein Tank 1400 is placed under gas pressure from a pressurized gas source through Pressurized Gas Tube 1410 to act as a gas spring to force the coating suspension in Tank 1400 through Delivery Tube 1420 to Spray Head 1310. In FIG. 7A, Plunger 1370 is shown in the actuated position where a portion of Plunger 1370 is urged into Valve Body 1340 to stop the flow of coating suspension through Spray Head 1310. FIG. 7B depicts Plunger 1370 in a refracted position that permits flow of coating suspension through Spray Head 1310 and Spray Nozzle 1320 to emit Spray 1440 forming Spray Pattern 1445 to coat a substrate, not shown. In certain embodiments, Tank 1400 may further include a device for mixing a suspension contained therein. In preferred embodiments, the mixer employs sonication and/or ultrasonication. In some embodiments, the mixer may include an impeller and/or mixing paddle.

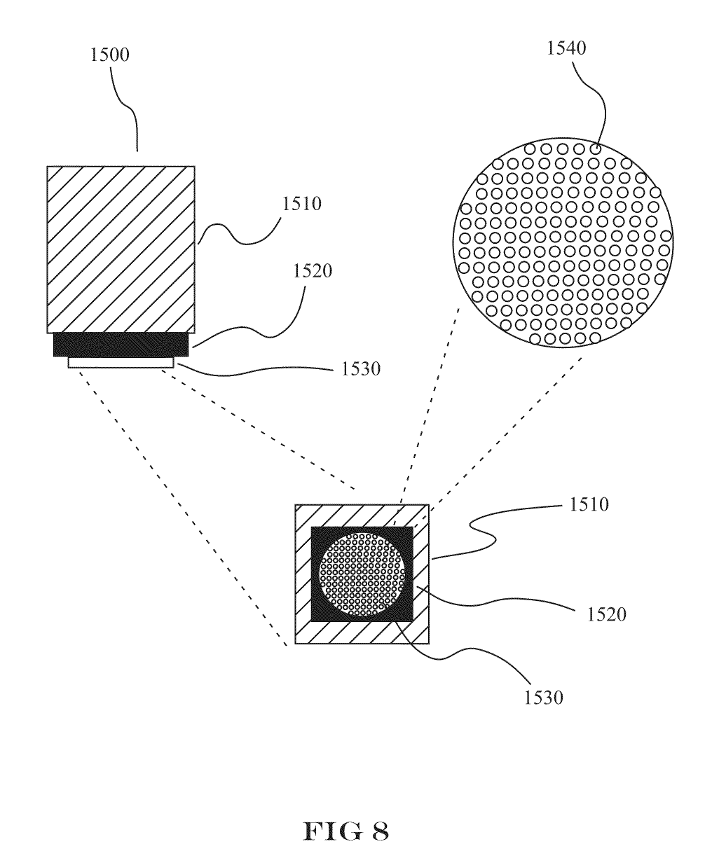

FIG. 8 depicts an ultrasonic multi-orifice spray head employed in a preferred embodiment of the invention. Ultrasonic Spray Head 1500 comprises, in preferred embodiments, Spray Body 1510 preferably has an internal flow control valve therein, not shown. Attached to Spray Body 1510 is Piezo Element 1520 to which Nozzle Array 1530 is attached thereto. Nozzle Array 1530 is in fluid communication with Spray Body 1510 such that when coating suspension is pumped into Spray Body 1510, and the valve, if any, is open, coating suspension can flow to Nozzle Array 1530 to be emitted through a plurality of Ports 1540. Piezo Element 1520 is energized by a power source to cause Piezo Element 1540 to experience the reverse piezo electricity effect achieving a volumetric displacement along an axis perpendicular to Nozzle Array 1530. The result is that Nozzle Array 1530 is moved back and forth along the axis perpendicular to Piezo Element 1540. In preferred embodiments, Piezo Element 1520 is energized and de-energized by the power source at frequencies between 10,000 Hz and 100,000 Hz. By varying the frequency applied to Piezo Element 1520, different drop sizes may be achieved for a given viscosity and pressure of the coating suspension. In preferred embodiments, strain-thinning coating suspensions are used to provide low viscosity under pressure and high viscosity once deposited upon a substrate. In some embodiments, the valve body is instead simply a body to permit flow of fluid and to support other parts of the spray head. In some embodiments, the Piezo element is located inside the valve body with a tube for transporting coating suspension to a nozzle and the element, in conjunction with the tube, act to pump and control the flow of coating suspension towards the nozzle or nozzles.

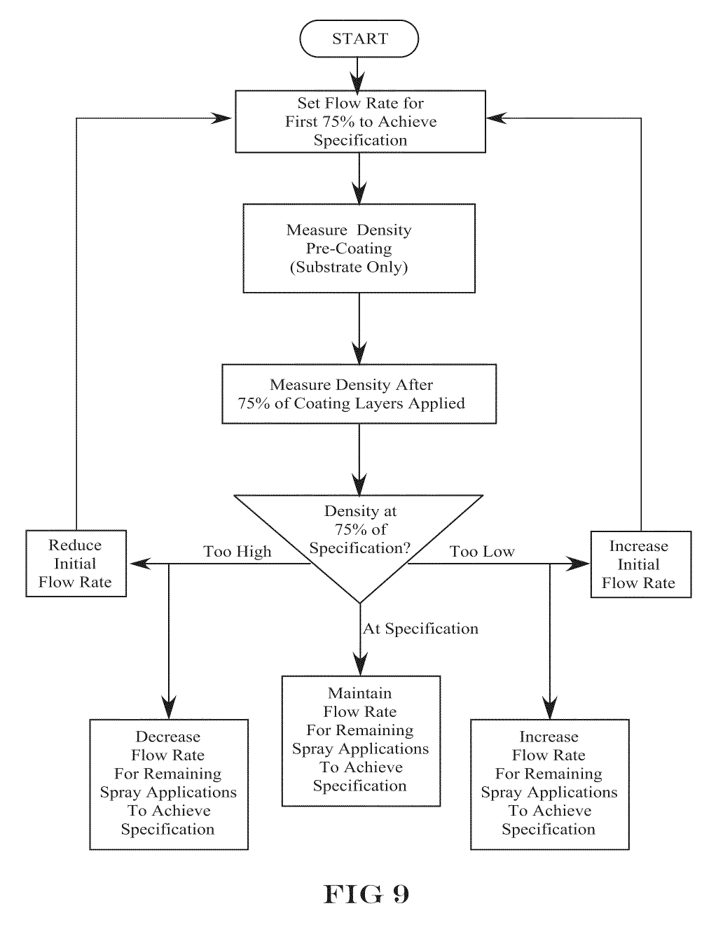

FIG. 9 depicts a flow-chart showing the logic flow of a proportional-integral-derivative controller (PID controller) feedback-loop operated spray deposition system of a preferred embodiment of the invention. The PID controller initially sets the first 75 percent of the spray regions to apply 75 percent of the final density specified for the coating. To establish a baseline for the substrate's density, the substrate's density is measured prior to spray coating. Then, after the substrate has passed through 75 percent of the spray regions, a second (interim) density measurement is made. From the second density measurement, the first density measurement is subtracted to determine the density of the coating thus far applied. The substrate is then coated at the pre-set flow rate to achieve the specified density. If the density of the coating thus far is too low, the flow rate of the final 25 percent of the spray regions is increased to provide for a final density according to specification. Also, the initial spray flow rate is increased to yield a coating density of 75 percent of specification at the second density measurement for subsequent substrate(s) coating. If the density of the coating at the second density measurement is too high, the flow rate for the final 25 percent of the spray regions is decreased to provide for a final density according to specification. Also, the initial flow fate is decreased to yield a coating density of 75 percent of specification at the second density measurement for subsequent substrate(s) coating. Variations of this system may, in some embodiments, further include including moisture detection to monitor drying rates in the drying regions to ensure that the coating is at the specified dryness prior to subsequent sprayings or final drying. Drying rates may, in some embodiments, may be altered by increasing temperature, air flow, or both in the drying regions.

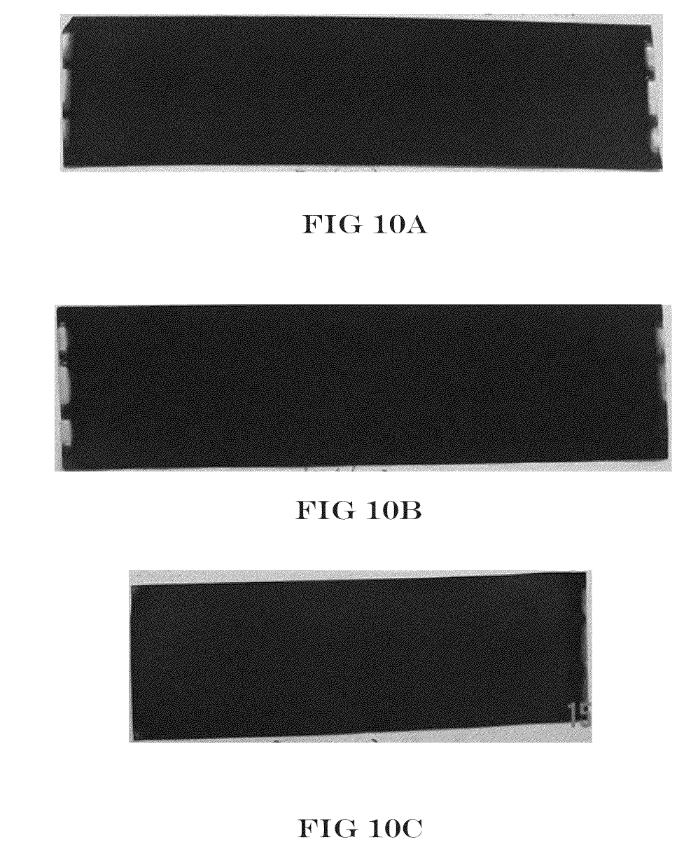

Images of coated electrodes are depicted in FIGS. 10A through 10C, wherein FIG. 10A depicts an electrode material loading of 2.5 mg/cm², 10B is loaded at 5.0 mg/cm², and 10C is loaded at 10 mg/cm². The coating is evenly distributed as evidenced by the consistent darkness across each electrode surface.

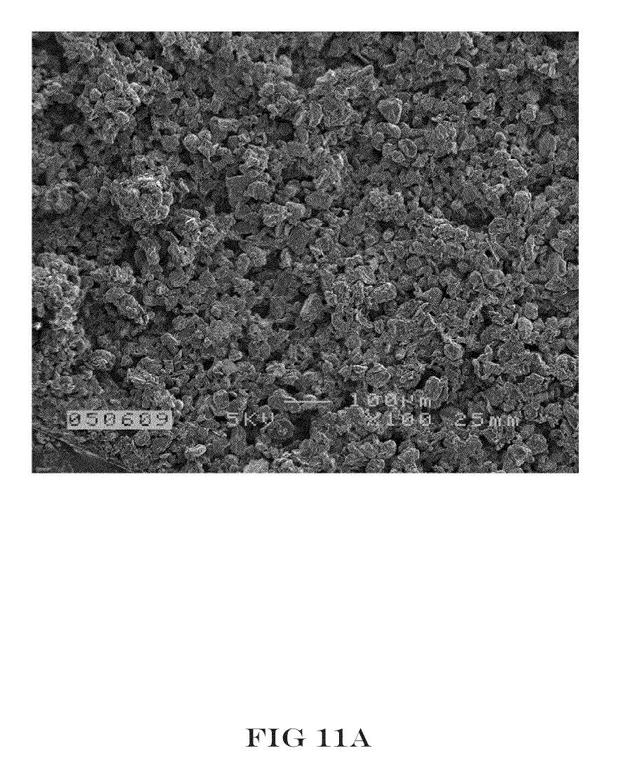

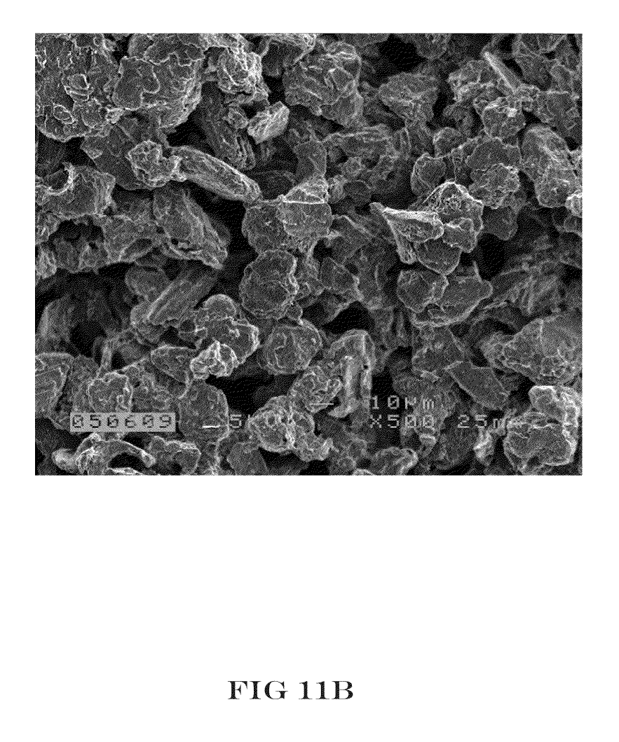

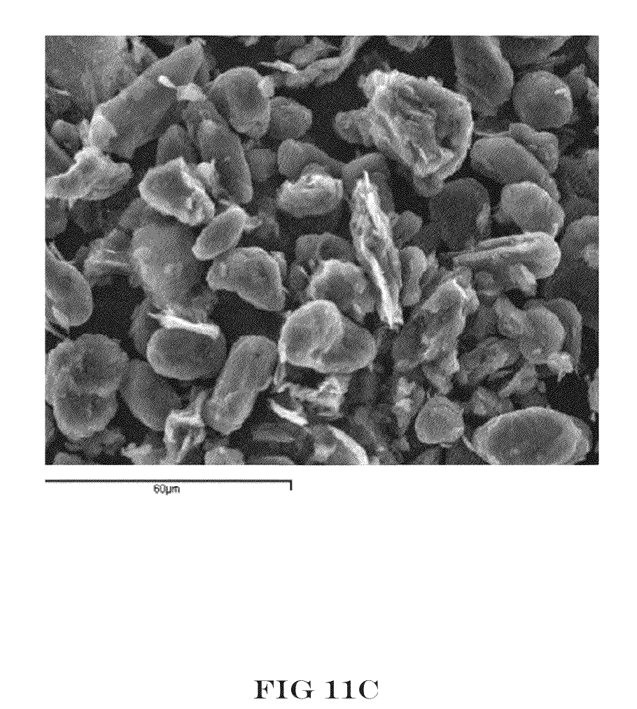

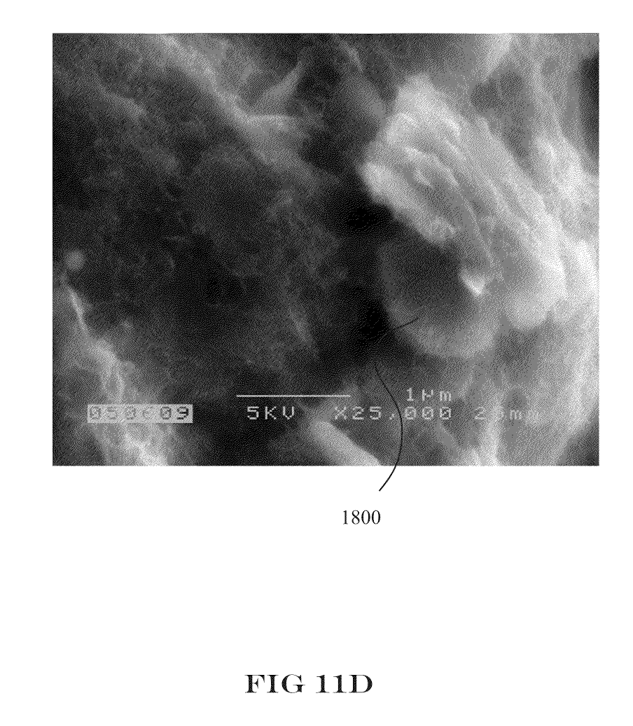

FIGS. 11A through 11D depict Scanning Electron Micrograph (SEM) images at 100×, 1,000×, 10,000×, and 100,000× magnification of an anode made using a preferred method of the invention. Of interest is FIG. 11D where Carbon Nanotubes 1800 can be seen among graphite particles having an average diameter of about 150 μm.

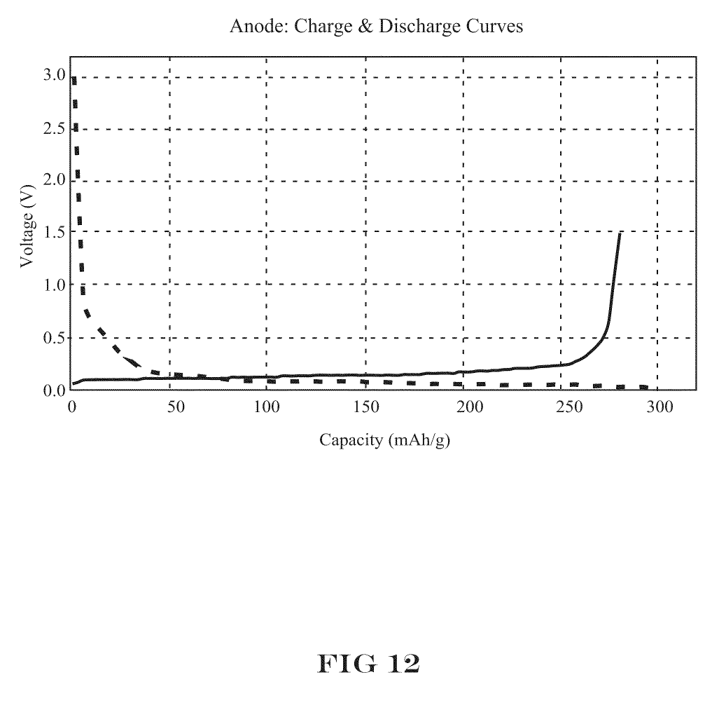

Turning to FIG. 12, an exemplary Charge & Discharge Curves are depicted for an anode produced using a preferred embodiment of the invention. The dashed line represents the 1^{st} discharge of the half-cell. The solid line represents the 1^{st} charge of the half-cell. The anode comprised graphite as the active material and carbon nanotubes for conductive particles. The binder Styrene-Butadiene Rubber (SBR) was also included in the coating suspension. According to the graph, the anode had a capacity of about 270mAh/g.

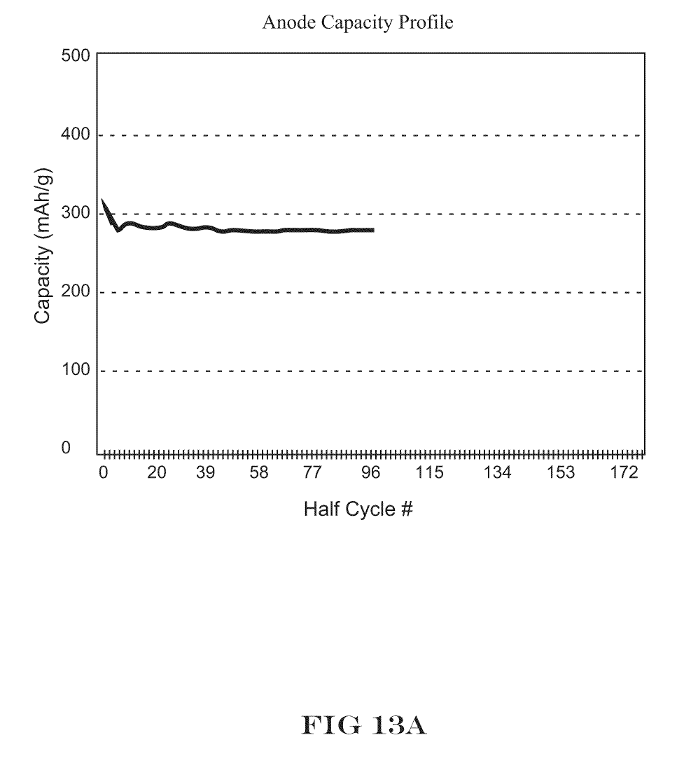

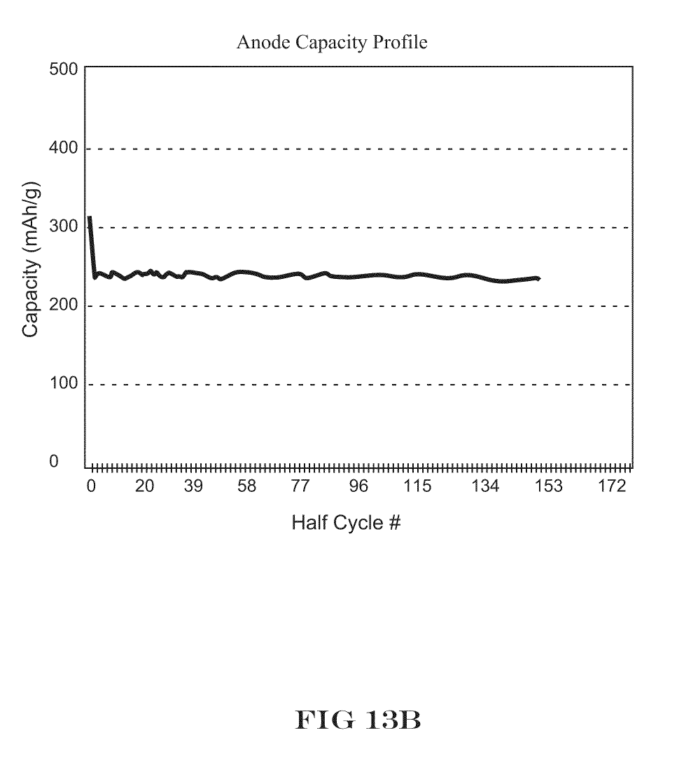

Anode capacity profiles we conducted on two replicate anodes as depicted in FIGS. 13A and 13B. Here, the half-cell data shows the anodes to be resistant to significant fade over about 100 cycles

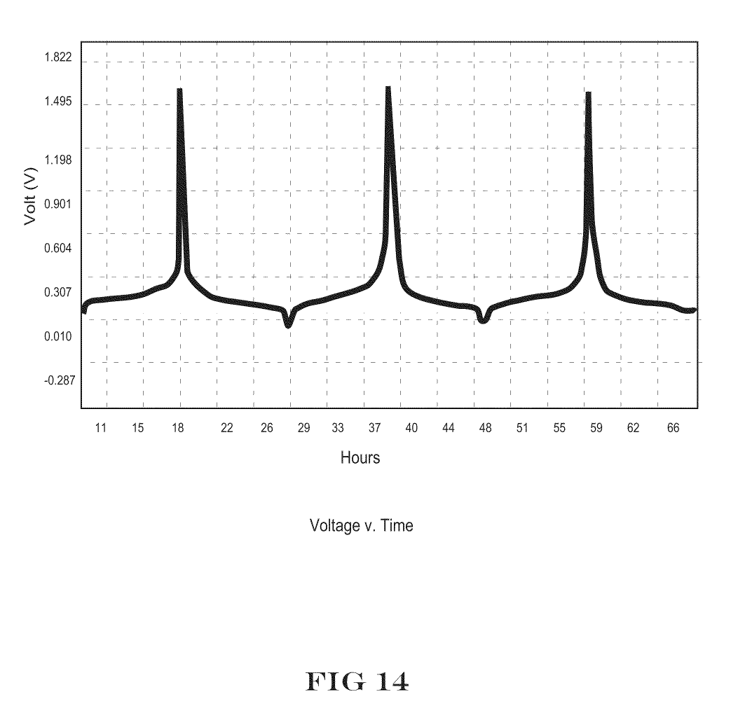

A voltage time curve is presented in FIG. 14 wherein the graph depicts approximately equal charge and discharge times suggesting that irreversible loss is relatively minimal.

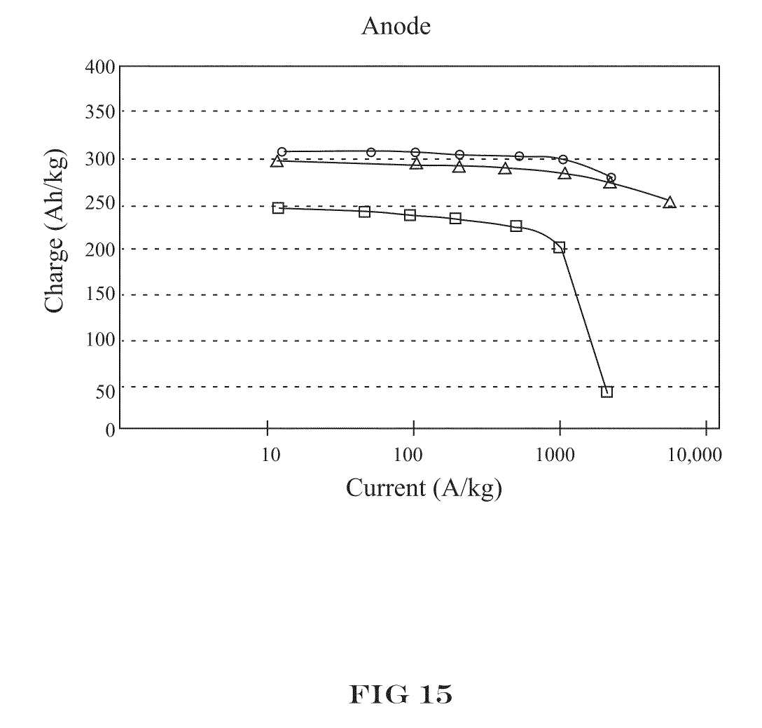

When compared to a commercially available graphite based anode, an anode produced by the preferred method of the invention yields an electrode with a higher power capacity by a margin of about 2× to 5× over the commercially available anode. FIG. 15 depicts a Current v. Charge graph wherein the lines represented by the circles and triangles are data derived from an anode produced using the preferred method of the invention. The line represented with squares was derived from a commercially available graphite anode.

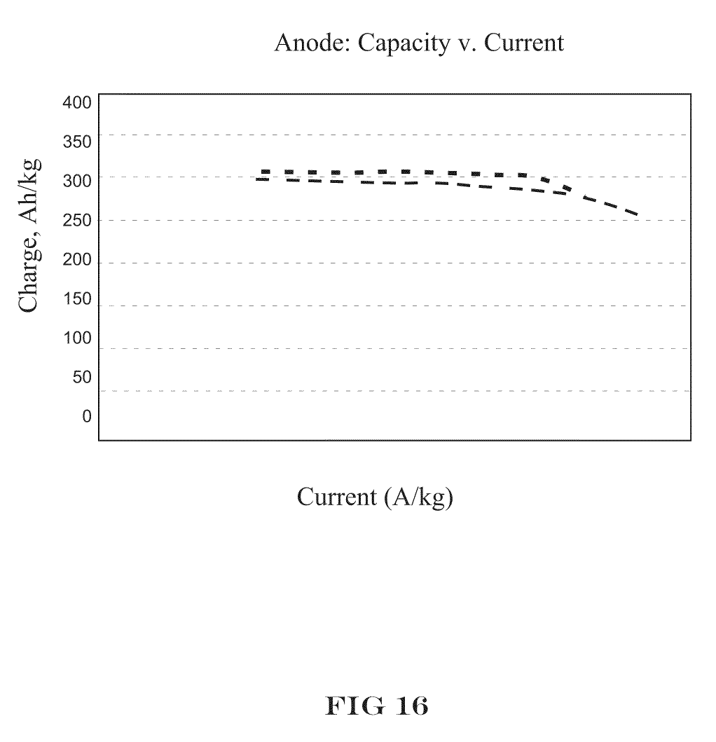

A Capacity v. Current graph for two replicate anodes is depicted in FIG. 16. Charge over a wide-range of current rates was well maintained.

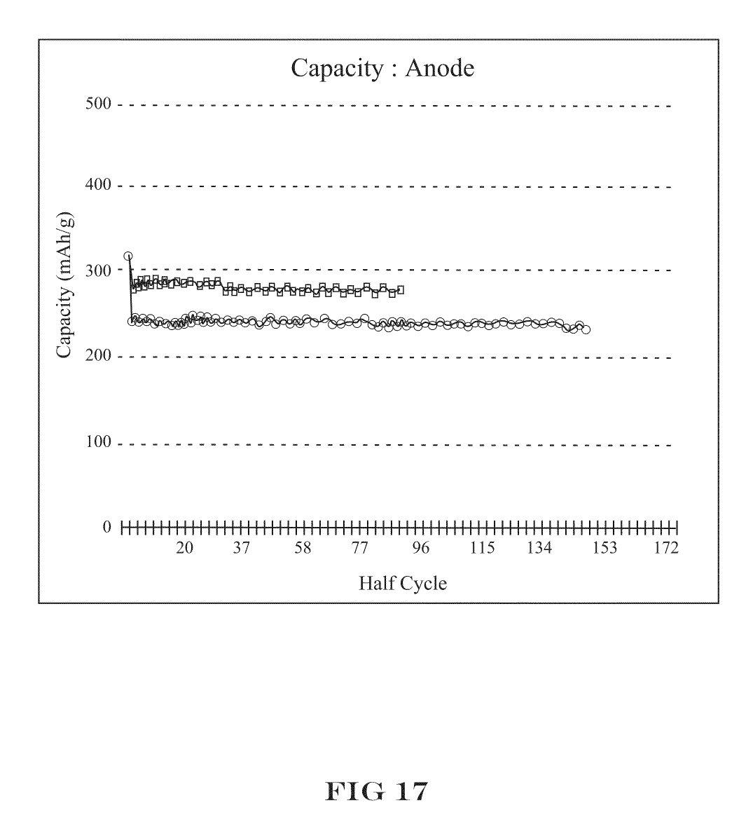

A Capacity v. Half-Cycle data is presented in FIG. 17 for two replicate anodes.

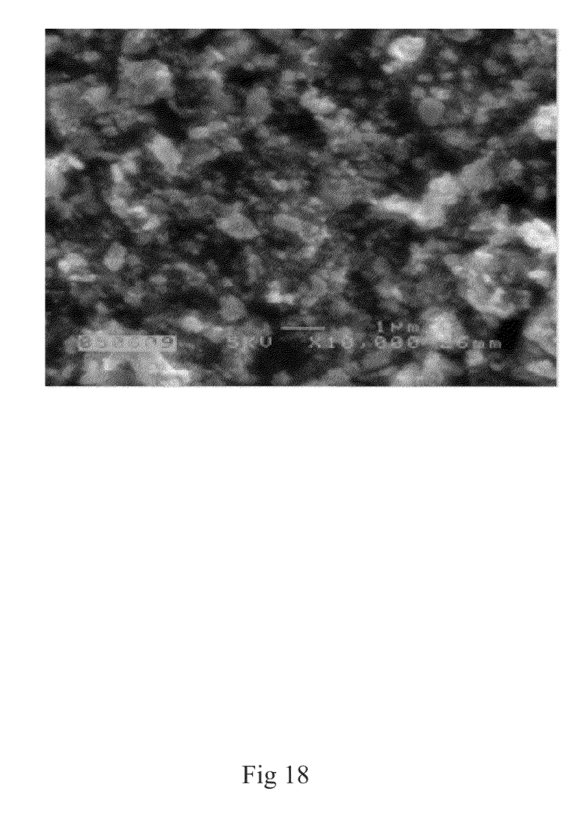

Images of coated electrodes made using a preferred method of the invention are depicted in FIGS. 18A and 18B, wherein FIG. 18A depicts an electrode material loading of 2.5 mg/cm², 18B is loaded at 15 mg/cm², and 10B is loaded at 30 mg/cm². The coating is evenly distributed as evidenced by the consistent darkness across each electrode surface.

A 10,000× SEM of a cathode made using a preferred method of the invention in

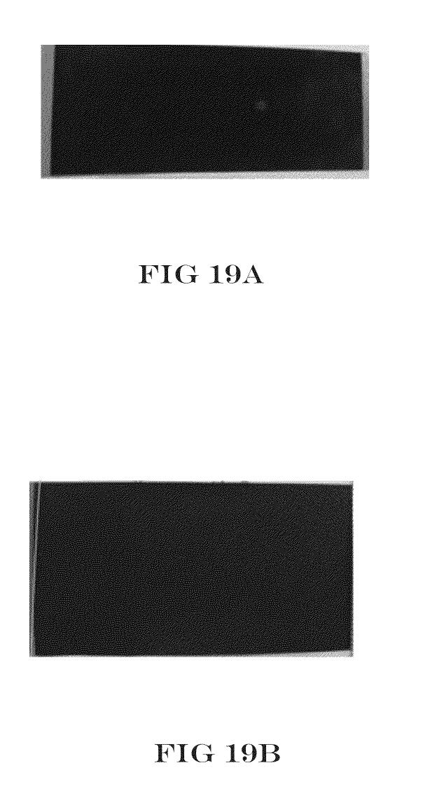

FIG. 19. The cathode comprised LiFePO₄, carbon nanotubes, and SBR binder.

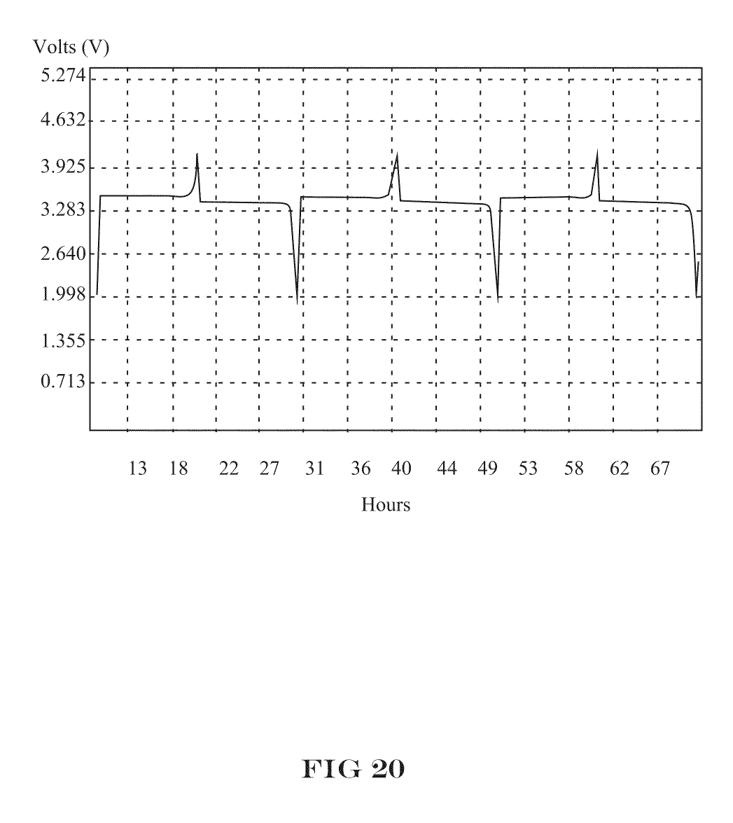

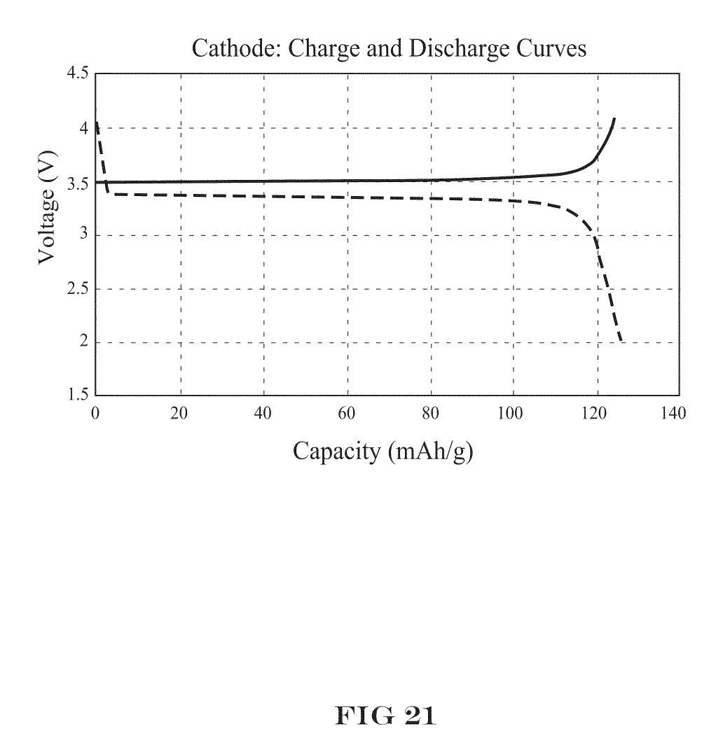

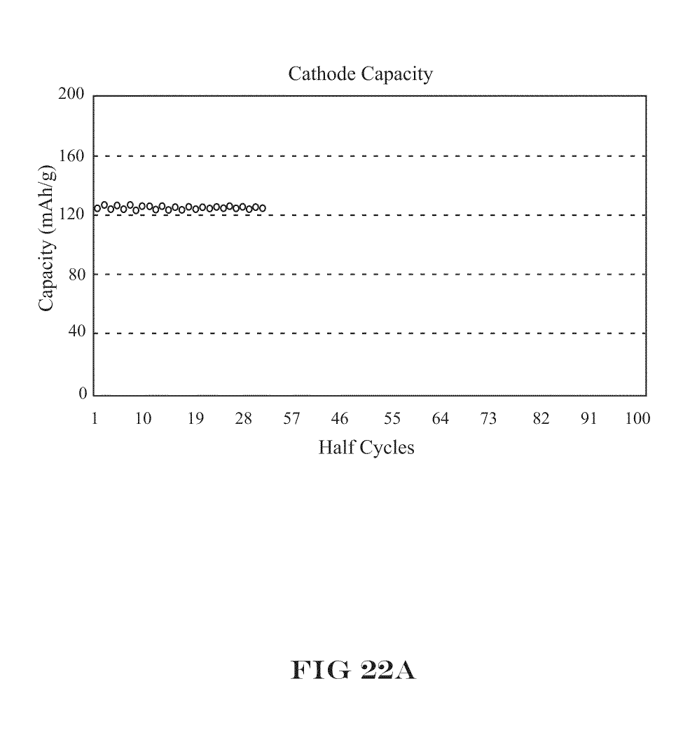

Charge and discharge data for a cathode made using a preferred method of the invention is depicted in FIG. 20. Of interest is that the time distances between the peak and valley of each cycle are approximately equal indicating good levels of reversible charge capacity. FIG. 21 represents the same data in a different format to better illustrate the charge time/discharge time differential, again indicating good reversible charge capacity.

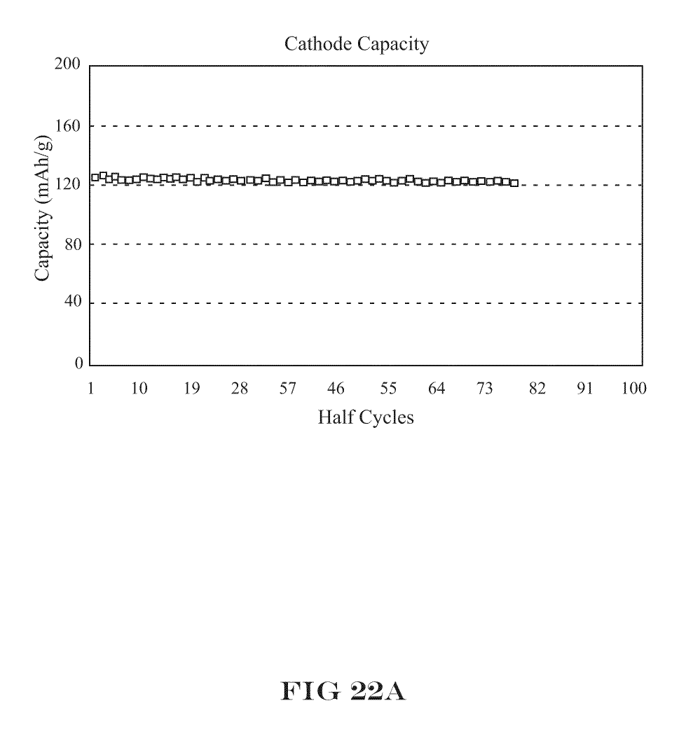

Fade was studied for a cathode made by a preferred method of the invention. Replicate cathodes were tested and the results depicted in FIGS. 22A and 22B, the latter showing minimal fade over 80 cycles.

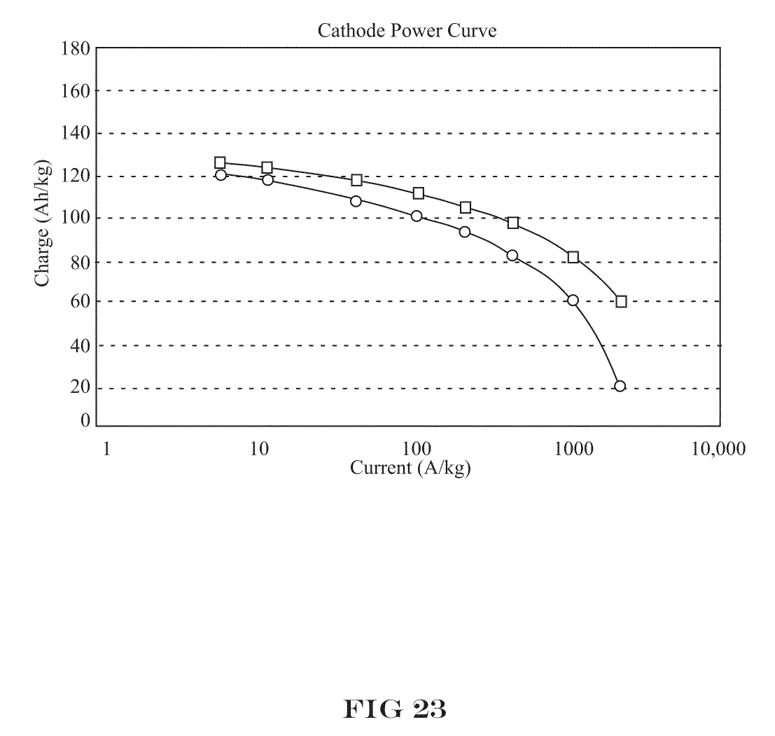

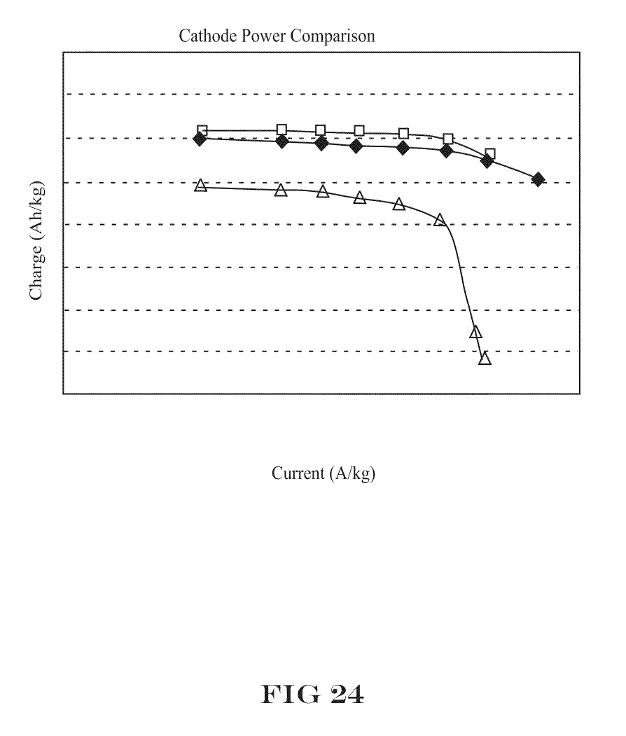

FIGS. 23 and 24 depict power curves for sample electrodes produced using a preferred method of the invention, the latter figure showing a commercially available electrode for comparison.

While the present invention has been described with reference to specific embodiments, it should be understood by those skilled in the art that obvious changes may be made and equivalents may be substituted without departing from the true spirit and scope of the invention. In addition, many modifications may be made to adapt the methods and devices of the present invention to particular situations, materials, compositions of matter, processes, process step or steps, to the objective, spirit and scope of the present invention. All such modifications are intended to be within the scope of the claims appended hereto.

### EXAMPLES

### Example 1

### Basic Spray/Dry Process

Basic spray/dry method was tested using an airbrush filled with a suspension containing:

Spraying was performed manually with a back and forth motion of the spray head parallel to the surface of the substrate. Approximately 40 passes were made to load the surface to a desired amount.

### Example 2

### Multi-step Spray/Dry Process

### Example 3

### Fabrication of Electrodes into a Cell

Circles were cut from each type of electrode (cathode/anode) in a size to fit into a pouch. A porous polymer sheet was placed between the electrodes as they were layered into the pouch. Electrolyte (LiPF₆) was added prior to vacuum sealing the pouch to form a pouch cell.

### Example 4

### Testing of Cell

The following protocol was followed to test cells made with the electrodes of the invention:
a) Measure open circuit voltage (OCV) (10 sec)
b) Apply 1 sec current pulse (0.5 mA for coin cells, 5-10 mA for pouch cells)
c) Measure voltage drop between OCV and the first 10 msec of applied pulse
d) Impedance testing: A few special cells, especially large pouch cells:
e) Measure impedance from 1000 kHz to 0.01 Hz

Anode Half-cells
a) Resistance test
b) Initial capacity test in constant current mode (3 cycles, starting with discharge cycle, each cycle running at 25 mA/g and then lowering to 12.5 mA/g until voltage limit is reached—designated “25+12.5 mA/g”)
   (a) For graphite ½-cells, voltage limits are 0.01V and 1.5V
   (b) For silicon ½-cells, voltage limits 0.07V to 1.0V
c) Resistance test
   i) Power test* up to 10 mA total current
   ii) followed by power test up to 20 mA, if charge withdrawn at 10 mA step is ≧70% total capacity
   iii) followed by power test up to 30 mA, if charge withdrawn at 10 mA step is ≧80% total capacity
d) fade testing: capacity test in constant current mode (100 cycles at “25+12.5 mA/g”, with a resistance and a power test every 25 cycles)

*Power test:
a) discharge down to lower voltage limit at “25+12.5” mA/g
b) charge at highest current until upper voltage limit
c) rest 5 minutes
d) charge at half the previous current
e) rest 5 minutes
f) etc., until the current is at or below 25 mA/g

Cathode Half-cells
a) Resistance test
b) Initial capacity test in constant current mode (3 cycles, starting with charge cycle, each cycle running at 12.5 mA/g and then lowering to 6.25 mA/g until voltage limit is reached—designated “12.5+6.25 mA/g”)
   i) For LiFePO4 ½-cells, voltage limits are 4.1V and 2.0V
   ii) For other cathode chemistries, voltage limits may be a few 0.1's of volts higher
c) Resistance test
d) Power test* up to 10 mA total current
   i) followed by power test up to 20 mA, if charge withdrawn at 10 mA step is ≧70% total capacity
   ii) followed by power test up to 30 mA, if charge withdrawn at 10 mA step is ≧80% total capacity
e) Fade testing: capacity test in constant current mode (100 cycles at “12.5+6.25 mA/g”, with a resistance and a power test every 25 cycles)

*Power Test:
a) charge up to upper voltage limit at “12.5+6.25 mA/g”
b) discharge at highest current until lower voltage limit
c) rest 5 minutes
d) discharge at half the previous current
e) rest 5 minutes
f) etc., until the current is at or below 12.5 mA/g

Full Cells (matched)
a) Resistance test
b) Initial capacity test in constant current mode (3 cycles, starting with discharge cycle, each cycle running at either “25+12.5 mA/g” (anode weight) or “12.5+6.25 mA/g” (cathode weight), whichever is smaller)
   i) For graphite anode and LiFePO4 cathode full cells, voltage limits are 2.0 and 4.1 V
   ii) For cells with other cathodes, voltage limits may be a few 0.1V higher
c) Resistance test
d) Power test* up to 10 mA total current
   i) followed by power test up to 20 mA, if charge withdrawn at 10 mA step is ≧70% total capacity
   ii) followed by power test up to 30 mA, if charge withdrawn at 10 mA step is ≧80% total capacity
e) Fade testing: capacity test in constant current mode (100 cycles at “25+12.5 mA/g” (anode) or “12.5+6.25 mA/g” (cathode), whichever is smaller, with a resistance and a power test every 25 cycles)

Test Equipment

For resistance and impedance tests: potentiostat/galvanostat
a) Princeton Applied Research: Versastat V3

For capacity and power: battery testers:
a) Manufacturer: Neware Technology Limited
b) Models (for different current ranges):
   i) BTS-5V10A(8CH) 10 mA limit
   ii) BTS-5V100A(8CH) 100 mA limit
   iii) BTS-5V200A(8CH) 200 mA limit

1. A method for coating a substrate comprising the steps of:
a) providing a substrate having a surface;
b) providing an active material suspension comprising:
i) active material particles, said active material particles capable of reversibly storing ions; and,
ii) electrically conductive particles; and,
iii) a solvent;
c) spraying said active material suspension onto said substrate surface to form a first coating layer;
d) evaporating a portion of said solvent, if any, from said first coating layer; and,
e) repeating said steps (c) through step (e) for at least two repetitions.

2.-13. (canceled)

14. The method of claim 1 wherein said active material suspension is sprayed using an aerosol sprayer.

15. The method of claim 1 wherein said active material suspension is sprayed using an airless sprayer.

16. The method of claim 1 wherein said active material suspension is sprayed using an ultrasonic sprayer.

17. The method of claim 1 wherein said active material suspension is sprayed using a pulse width modulated sprayer.

18. The method of claim 1 wherein said active material suspension is sprayed using electro-spray deposition.

19. The method of claim 1 wherein said active material suspension is sprayed in a volumetrically controlled manner.

20. The method of claim 1 wherein said evaporating step further comprises detecting the amount of solvent in said coating layer.

21.-28. (canceled)

29. The method of claim 1 wherein the thickness of said coating layer is measured prior to said repeating of said spraying and evaporating steps.

30. The method of claim 1 wherein the density of said coating layer is measured prior to said repeating of said spraying and evaporating steps.

31.-38. (canceled)

39. The method of claim 1 wherein said spraying step is operationally linked to a detector monitoring at least one attribute of the coating layer so that the spray volume is adapted in real-time in response to control, wholly or partly, a degree of said attribute.

40.-45. (canceled)

46. The method of claim 1 wherein a subsequent coating layer comprises materials different from said active material particles and said electrically conductive particles.

47.-78. (canceled)

79. The method of claim 1 wherein said active material particles comprise an anode active material capable of reversibly storing an ion.

80. The method of claim 1 wherein said active material particles further comprise lithium ions stored therein.

81.-130. (canceled)

131. The method of claim 1 wherein said electrically conductive particles comprise carbon.

132. (canceled)

133. The method of claim 131 wherein said carbon comprises carbon nanotubes.

134.-138. (canceled)

139. The method of claim 1 wherein said active material suspension further comprises carboxymethylcellulose/styrene butadiene rubber.

140.-239. (canceled)

240. The system of claim 237 wherein said plurality of spray/dry regions comprises at least ten spray/dry regions.

241. The system of claim 237 wherein said plurality of spray/dry regions comprises at least twenty spray/dry regions.
